(19) United States
(12) Patent Application Publication
(10) Pub. No.: US 2013/0187195 A1
(43) Pub. Date: Jul. 25, 2013

(54) Power Transistor

(71) Applicant: Hubert Rothleitner, Villach (AT)

(72) Inventor: Hubert Rothleitner, Villach (AT)

(73) Assignee: INFINEON TECHNOLOGIES AUSTRIA AG, Villach (AT)

(21) Appl. No.: 13/356,705

(22) Filed: Jan. 24, 2012

(51) Int. Cl. H01L 29/739

(52) U.S. Cl. 257/139; 257/E29.198

(57) ABSTRACT

A cell field has an edge and a center, an individual device cells are connected in parallel. A first type of device cells has a body region with a first size and a source region with a second size implemented in the body region, and a second type of device cells has a body region of the first size and in which a source region is omitted or the source region is smaller than the second size. The cell field includes non-overlapping cell regions, each including the same plurality of device cells. At least one sequence of cell regions is arranged between the edge and center of the cell field in which the frequency of device cells of the second type monotonically increases from cell region to cell region in the direction of the center, and one cell region of the sequence of cell regions includes or adjoins the center.

### TECHNICAL FIELD

Embodiments of the present invention relate to a power transistor, in particular a power transistor having a plurality of transistor cells.

### BACKGROUND

Transistors, such as MOSFETs (metal oxide semiconductor field effect transistors) or IGBTs (insulated gate bipolar transistors), are widely used as electronic switches in different kinds of applications, such as inverters, voltage regulators, current regulators, or drive circuits for driving electric loads, such as lamps, valves, motors, etc. Transistors that are usually employed as electronic switches are power transistors having a plurality of identical transistors cells arranged in a transistor cell field and connected in parallel.

Modern power transistors are optimized to have a low on-resistance (R_{ON}) at high load currents. In these transistors, however, stability problems may occur when they are not operated as a switch, but in linear operation under low load conditions, which is when a low load current flows through the transistors at a high drain-to-source voltage (V_{DS}). Inevitably, energy is dissipated in a transistor that is active, depending on the time. The dissipation of energy causes a semiconductor body in which the transistor is implemented to be heated. The characteristic curves of modern power transistors are such that at high load conditions the load current decreases when at a given high drive voltage (gate-source voltage V_{GS}) the temperature increases. By virtue of this negative thermal feedback a further heating of transistor cells having a higher temperature than other transistors cells is reduced. At low load conditions, however, there is a positive thermal feedback so that at a given low drive voltage a temperature increase results in an increased load current. The increased load current results in a further increase of the temperature, and so on. When there are transistor cells having a higher temperature than other transistor cells, the current through these transistor cells increases, resulting in an unbalanced distribution of the overall load current to the individual transistor cells. In a worst case scenario the overall load current flows through only some transistor cells that are finally destroyed. This phenomenon is known as current filamentation.

There is, therefore, a need to provide a transistor that is robust under high load conditions as well as under low load conditions.

### SUMMARY

A first embodiment relates to a transistor device including a plurality of device cells arranged in a cell field having an edge and a center, the individual device cells connected in parallel. The device cells include a first type of device cells having a body region with a first size and a source region with a second size implemented in the body region, and include a second type of device cells having a body region of the first size and in which a source region is omitted or in which the source region is smaller than the second size. The cell field includes a plurality of non-overlapping cell regions, each including the same plurality of device cells, wherein there is at least one sequence of cell regions arranged between the edge and the center of the cell field in which the frequency of device cells of the second type monotonically increases from cell region to cell region in the direction of the center, wherein one cell region of the sequence of cell regions includes or adjoins the center.

Those skilled in the art will recognize additional features and advantages upon reading the following detailed description, and upon viewing the accompanying drawings.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates exemplary characteristic curves of a power transistor.

FIG. 2 schematically illustrates a cell field of a power transistor integrated in a semiconductor body, the cell field including transistor cells of a first type and transistor cells of a second type.

FIG. 3 schematically illustrates a vertical cross sectional view of first type and second type transistor cells according to a first embodiment.

FIG. 4 schematically illustrates a horizontal cross sectional view of first type and second type transistor cells according to a first embodiment.

FIG. 5 schematically illustrates a horizontal cross sectional view of first type and second type transistor cells according to a second embodiment.

FIG. 6 schematically illustrates a vertical cross sectional view of first type and second type transistor cells according to a second embodiment.

FIG. 7 schematically illustrates a vertical cross sectional view of first type and second type transistor cells according to a third embodiment.

FIG. 8 illustrates a horizontal cross sectional view of the transistor cells of FIG. 7.

FIG. 9 illustrates the distribution of transistor cells of the second type in the cell field according to a first embodiment.

FIG. 10 schematically illustrates a cell field of a power transistor according to a further embodiment.

### DETAILED DESCRIPTION

In the following Detailed Description, reference is made to the accompanying drawings, which form a part thereof, and in which is shown by way of illustration specific embodiments in which the invention may be practiced. In this regard, directional terminology, such as “top”, “bottom”, “front”, “back”, “leading”, “trailing” etc., is used with reference to the orientation of the FIGs. being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

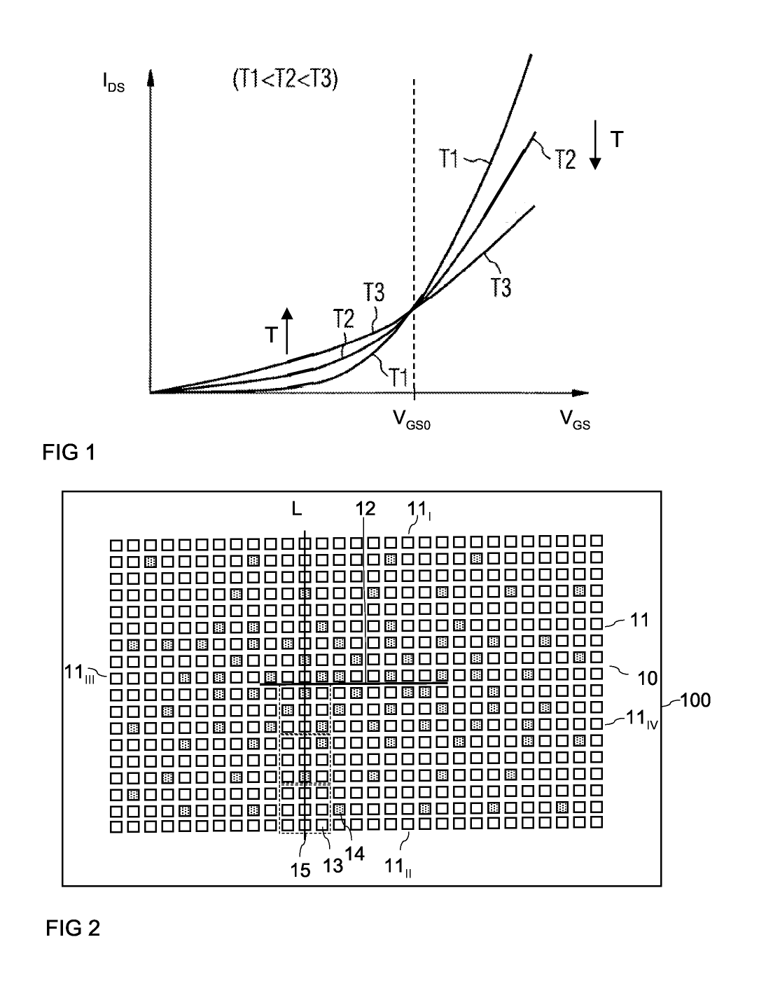

FIG. 1 schematically illustrates characteristic input-curves of an MOS-transistor, such as a MOSFET or an IGBT. In FIG. 1, three different characteristic curves are shown each illustrating the dependency of a load current I_{DS} on a drive signal or drive voltage V_{GS}. The load current is, e.g., a drain-source current in a MOSFET or a collector-emitter current in an IGBT. The drive signal is, e.g., a gate-source voltage in an MOSFET or a gate-emitter voltage of an IGBT. FIG. 1 illustrates three characteristic curves obtained at three different temperatures T1, T2, T3, with T1<T2<T3. As can be seen from FIG. 1, the threshold voltage, which is the drive voltage at which the transistor starts to conduct the load current Iₚₛ, is dependent on the temperature and decreases with decreasing temperature. At higher values of the drive voltage V_{GS} the load current I_{DS} decreases when the temperature T increase. This results from lower charge carrier mobility at higher temperatures. These two effects, namely the decreasing threshold voltage with increasing temperature and the decreasing load current I_{DS} at increasing temperature, results in a temperature stable point that is defined by a drive signal V_{GSO} at which the load current I_{DS} is independent of the temperature.

As can be seen from FIG. 1, a rising temperature at a drive signal V_{GS} below V_{GSO} results in an increasing load current I_{DS}. Since a rising load current may result in a rising temperature of the transistor, there is a positive thermal feedback at drive signals below the stable point V_{GSO}. At drive signals V_{GS} above V_{GSO} there is a negative thermal feedback, because at these drive signals the load current I_{DS} decreases with increasing temperature.

Operating the transistor at drive signals V_{GS} below the stable point V_{GSO} may result in instabilities such that a rising load current I_{DS} may result in a rising temperature, which again may result in an increase of the current. In particular in a transistor with a cell structure, which is a transistor having a plurality of transistor cells connected in parallel, the temperature distribution in the transistor may be not homogenous. In this case, operating the transistor at drive signals at which a positive thermal feedback may occur, may have the effect that transistor cells having the highest temperature take the highest share of the current flowing through the transistor. Taking the highest share of the current may result in a further heating of these transistor cells, which in turn may result in a yet higher share of the current flowing through these transistor cells until some of the transistor cells are destroyed. This effect is known as current filamentation.

Current filamentation problems can be prevented when the drive signal is generated to be always above the temperature stable point V_{GSO}. However, operation scenarios of an MOS transistor may occur in which this cannot be guaranteed, e.g., when the MOS transistor is operated in a linear current or voltage regulator or in a clamping circuit (active Zener circuit) in which the MOS transistor is used to dissipate energy stored in an inductive load. Further, in some types of MOS transistors the temperature stable point V_{GSO} is at considerable high values of the drive signal V_{GS}, which makes this problem even worse.

Although the load current I_{DS} is low when the transistor is operated in a region where positive thermal feedback may occur, the load voltage (drain-source voltage V_{DS} in a MOSFET) can be considerably high. The power dissipated in the transistor is given by the product of the load current I_{DS} and the load voltage V_{DS}, so that even at low load currents considerable power can be dissipated in the transistor when the load voltage V_{DS} is high.

FIG. 2 schematically illustrates a horizontal cross sectional view of a semiconductor body 100 in which a plurality of device cells, e.g. transistor cells, are implemented in a cell field 10. Just for illustration purposes the cell field 10 has a rectangular shape in the embodiment illustrated in FIG. 2.

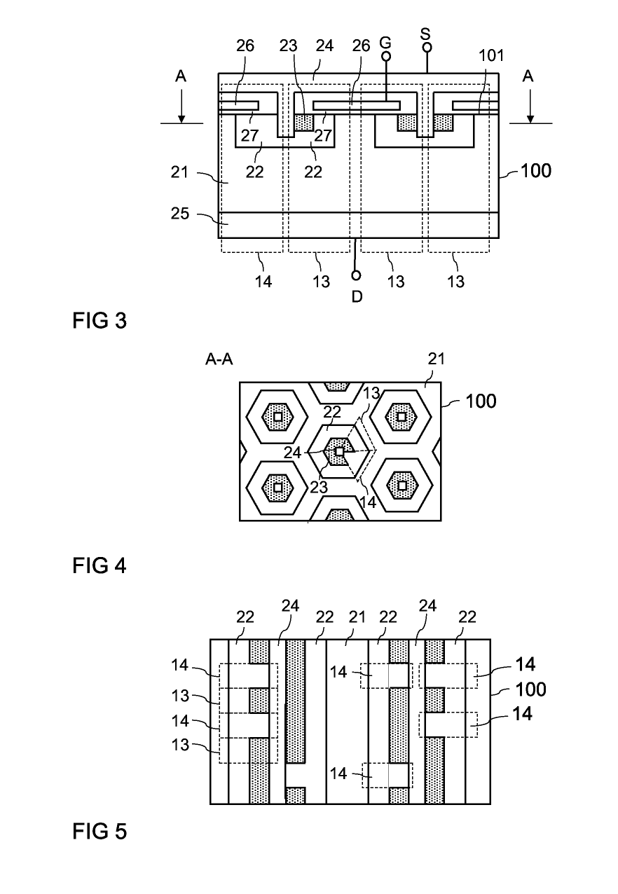

The transistor device includes device cells of a first type 13 and device cells of a second type 14. The difference between the first type device cells 13 and the second type device cells 14 is explained with reference to FIGS. 3 to 8 below. In FIG. 2, the individual device cells 13, 14 are drawn as rectangles. However, this is only an example and only serves to illustrate the distribution of first type device cells 13 and second type device cells 14 in the cell field 10. Further, in FIG. 2, the individual device cells, 13, 14 are drawn to be mutually distant. However, this is only an example. The device cells 13, 14 could also be implemented such that adjacent device cells adjoin each other.

The cell field 10 is a region of the semiconductor body 100 in which the device cells 13, 14 are implemented. The cell field 10 basically has a rectangular shape in the embodiment illustrated in FIG. 2. However, this is only an example. The cell field 10 could be implemented with shapes other than a rectangular shape as well. The cell field 10 has an edge 11 surrounding the cell field 10 and a center 12 distant to the edge 11. The edge 11 and the center 12 are not structural features, but are merely geometrical features defined by the form of the cell field 10. The center 11 can include only one point, can include a plurality of adjoining points (a line) or can include two or more points that are distant. The center 12 is equidistant to at least two sections of the edge 11 on opposite sides of the cell field 10. In the embodiment illustrated in FIG. 2, in which the cell field 10 has a rectangular shape, the center 12 is a line parallel to first and second edge sections 11_{I}, 11_{II} on opposite sides of the cell field 10. The center line 12 is equidistant to the first and second edge sections 11_{I}, 11_{II}. A first longitudinal end of the center line 12 faces a third edge section 11_{III}, and a second longitudinal end faces a fourth edge section 11_{IV}, where the distance between the first longitudinal end and the third edge section 11_{III} equals the distance between the second longitudinal end and the fourth edge section 11_{IV}, and these distances equal the distances between the center line 12 and the first and second edge sections 11_{I}, 11_{II}. Dependent on the geometry of the cell field 10, the shape of the center 12 may, of course, vary.

As will be explained in further detail below, the second type device cells 14 are implemented such that in these device cells less energy is dissipated than in the first type device cells 13. In order to more equally distribute the dissipation of energy in the cell field 10, the frequency of second type device cells 14 increases toward the center 12 of the cell field 10. Specifically, the cell field 10 comprises a plurality of non-overlapping cell regions 15, with each cell region 15 comprising the same plurality of device cells. There is at least one sequence of cell regions arranged between the edge 11 and the center 12 of the cell field 10 in which the frequency of second type device cells 14 monotonically increases from cell region 15 to cell region 15 in the direction of the center 12, wherein one cell region of the sequence of cell regions includes or adjoins the center 12. In FIG. 2, a sequence of three cell regions 15 (illustrated in dashed lines) is schematically illustrated for illustration purposes. These cell regions 15 are non-overlapping and each include the same number of nine device cells. The number of second type device cells 14 in these cell regions 15 is monotonically increasing, where in this specific embodiment a first cell region 15 adjoining the edge 11 includes zero second type device regions 14, a second cell region adjoining the first cell region includes two second type device regions 14, and a third cell region adjoining the second cell region and the center 12 includes three second type device cells 14. Implementing the individual cell regions 15 with nine device cells is only an example. The individual cell regions 15 can be implemented with any other number of device cells as well. “To monotonically increase” means that in the sequence of cell regions 15 one cell region that is closer to the center 12 than an adjacent cell region 15 has more second type device cells 14 than the adjacent cell region 15 or has at least the same number of second type device cells 14 as the adjacent cell region 15. Further, the cell region of the sequence that is most distant to the center 12 has less second type device regions 14 than the cell region 15 including the center 12.

According to one embodiment, the number of second type device cells 14 increases strictly monotonically in the direction of the center 12. In this case, one cell region that is closer to the center 12 than an adjacent cell region 15 has more second type device cells 14 than the adjacent cell region 15.

The individual device cells 13, 14 each have a body region with a first size. The first type device 13 cells further each have a source region of a second size implemented in the body region, and the second type device cells 14 either have a source region smaller than the second size or are implemented such that the source region is omitted (the size of the source region is zero). The body and source regions are not illustrated in FIG. 2. Some different embodiments of implementing first type device cells and second type device cells are explained with reference to FIGS. 3 to 8 below.

FIG. 3 schematically illustrates a vertical cross sectional view of the semiconductor body 100 according to a first embodiment. FIG. 3 illustrates a section of the cell field 10 in which four device cells 13, 14, namely three first type device cells 13 and one second type device cell 14 are implemented.

The transistor device of FIG. 3 is implemented as a vertical (power) transistor device. Each of the first type and second type device cells (transistor cells) 13, 14 includes a body region 22 of a first size. The “size” of the body region 22 is the dimension in the horizontal plane, which is a plane perpendicular to the vertical plane shown in FIG. 3. The first type device cells 13 each further include a source region 23 implemented in the body region 22. The source regions 23 have a second size in the horizontal plane, wherein the second size is smaller than the first size of the body regions 22. The body region 22 and the source regions 23 are doped semiconductor regions. The source region 22 is doped complementary to the body region 22, and the doping type of the source region 23 defines the type of the transistor. In an n-type transistor (n-type MOSFET) the source region 23 is n-doped and the body region 22 is p-doped, while in a p-type transistor (p-type MOSFET) the source region 23 is p-doped, while the body region 22 is n-doped.

The second type device cells 14 either have a source region smaller than the second size of the source regions 23 in the first type device cells, or (as illustrated in FIG. 3) do not include a source region (have a source region of zero size).

Referring to FIG. 3, the individual device cells 13, 14 further include a drift region 21 and a drain region 25. The drift region 21 adjoins the body region 22 and has the same doping type as the source region 23, and the drain region 25 adjoins the drift region 21. The drift region 21 is located between the drain region 25 and the body region 22. In the embodiment illustrated in FIG. 3, the individual device cells 13, 14 share one common drift region 21 and share one common drain region 25. The transistor can be implemented as a MOSFET or can be implemented as an IGBT. In a MOSFET the drain region 25 has the same doping type as the source region 23 and the drift region 21 and is more highly doped than the drift region 21. In an IGBT, the drain region 25 has a doping type that is complementary to the doping type of the source region 23 and the drift region 21.

At least the first type device cells 13 further include a gate electrode 26 adjacent the body region 22 and dielectrically insulated from the body region 22 by a gate dielectric 27. In a conventional manner the gate electrode 26 serves to control a conducting channel in the body region 22 between the source region 23 and the drift region 21. In the embodiment illustrated in FIG. 3, the individual transistor cells are implemented with a planar gate electrode 26. In this case, the gate electrode 26 is implemented above a first surface 101 of the semiconductor body 100. According to one embodiment, the transistor device includes one gate electrode 26 that is common to the individual device cells. In FIG. 3, several sections of this common gate electrode 26 are shown. The gate electrode 26 is connected to a gate terminal G of the transistor device, the drain region 25 is connected to a drain terminal D and a source electrode 24 forms or is connected to a source terminal S. The source electrode 24 is electrically connected to the body regions 22 of the first type and the second type device cells 13, 14 and is connected to the source regions 23 in the first type device cells 13. When the second type device cells 14 are also implemented with source regions, the source electrode 24 is also connected to the source regions 23 in the second type device cells 14.

In the horizontal plane different shapes of the individual device cells 13, 14 are possible. Referring to FIG. 4, that shows a horizontal cross sectional view of the transistor device of FIG. 3 in a horizontal section plane A-A, the individual device cells can be implemented with a triangular shape. The shape of the device cells in the horizontal plane A-A is defined by the shape of the body region 22 in the horizontal plane. In the embodiment of FIG. 4, the individual device cells are implemented such that the body region 22 of six device cells forms a hexagon. However, this is only an example. Any other type of polygon may be formed by a plurality of triangular body regions as well. Further, the individual device cells are not restricted to be implemented with triangular body regions. The individual device cells could be implemented with rectangular body regions, circular body regions or elliptical body regions as well.

In FIG. 4, one second type device cell 14 is shown. The other device cells illustrated in FIG. 4 are first type device cells 13. In the embodiment of FIG. 4, different types of device cells can be implemented within one hexagonal structure, so that one hexagonal structure contains between 100% and 0% first device cells 13 versus between 0% and 100% second type device cells 14. According to a further embodiment, the individual device cells forming one hexagonal structure have the same type, so that one hexagonal structure either includes first type device cells 13 or includes second type device cells 14,.

The gate electrode 26 is out of view in the horizontal section plane illustrated in FIG. 4. This gate electrode 26 can be implemented such that it covers the individual device cell and includes contact holes above the source regions 23, where the source electrode 24 contacts the source regions 23 and the body regions 22.

FIG. 5 illustrates a horizontal view in the section plane A-A of a transistor device according to a further embodiment. In this embodiment, the body regions of the individual device cells 13, 14 have a rectangular shape, where the body regions of a plurality of device cells are arranged in line so as to form an elongated body structure. According to one embodiment, one of these elongated body structures extends from one edge to an opposite edge of the cell field 10 (not illustrated in FIG. 5), such as between edges 1_{I}, 1_{II} of FIG. 2. The source regions of the first type device cells 13 also have a rectangular shape in the embodiment of FIG. 5. In the second type device cells 14 the source regions are omitted in this embodiment. In FIG. 5, six second type device cells 14 are illustrated, the other device cells illustrated in FIG. 5, are first type device cells 13.

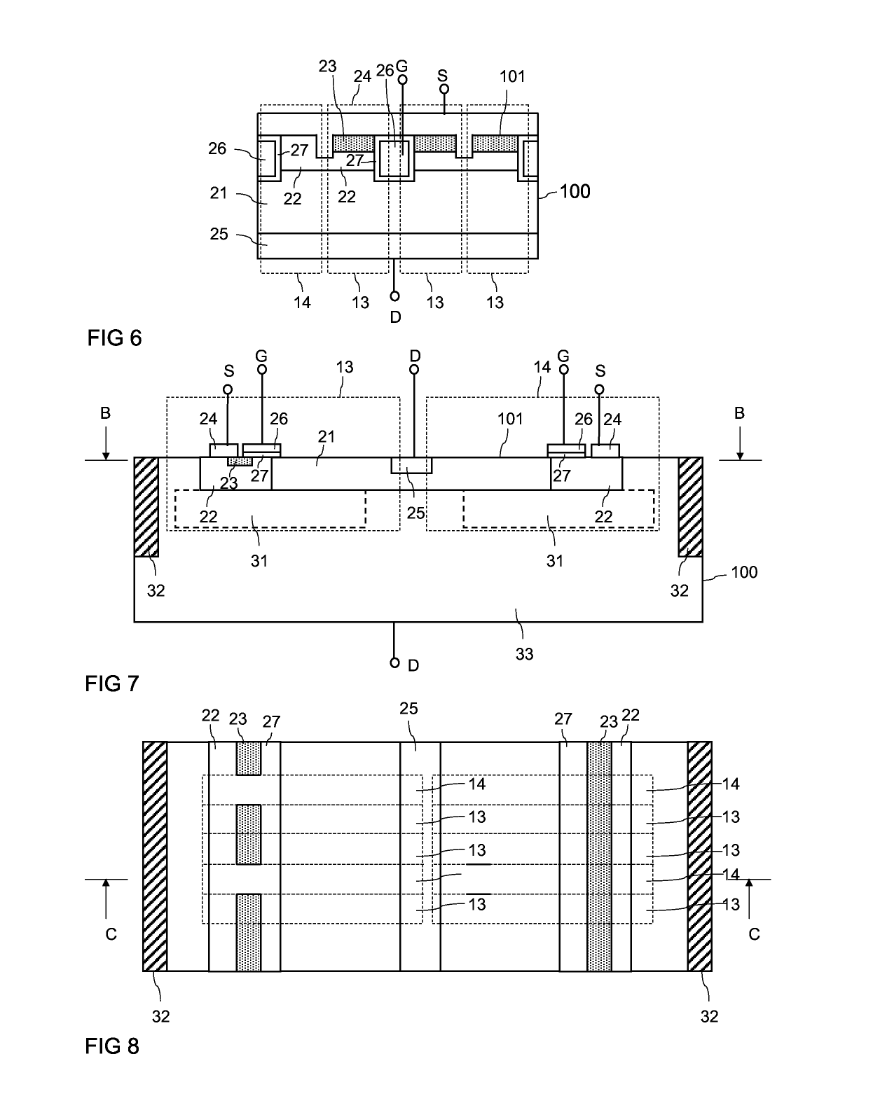

FIG. 6 illustrates a vertical cross sectional view of a transistor device according to a further embodiment. In this transistor device the gate electrode 26 is implemented in a trench extending from the first surface 101 into the semiconductor body 100. In the horizontal plane, the transistor device as illustrated in FIG. 6 can be implemented with any of the shapes explained with reference to FIGS. 4 and 5 above.

FIG. 7 illustrates a vertical cross sectional view of a transistor device according to a further embodiment. The transistor device of FIG. 7 is a lateral transistor device, which means that the body regions 22 and the drain regions 25 of the individual device cells 13, 14 are distant in a lateral direction of the semiconductor body 100. FIG. 7 shows a vertical cross sectional view of two device cells that have a common drain region 25. From the two device cells illustrated in FIG. 7, one device cell is a first type device cell 13 and includes a source regions 23 in the body region 22, and the other device cell is a second type device cell 14 in which the source region 23 is omitted. The drift region 21 extends from the body region 22 to the drain region 25 and encloses the drain region 25 in this embodiment. Optionally, a semiconductor region 31 of a doping type complementary to the doping type of the drift region 21 is located below the drift region 21 in a vertical direction of the semiconductor body 100 and adjoins the body region 22. Remaining sections 33 of the semiconductor body 100 may have a basic doping of the same doping type as the drift region 21. However, the doping concentration of these sections 33 can be lower than the doping concentration of the drift region 21.

Referring to FIG. 7, the device cells sharing one drain region 25 can be separated from other device cells (not illustrated) by dielectric regions 32 extending from the first surface 101 in a vertical direction of the semiconductor body 100.

FIG. 8 shows a horizontal view of the transistor device of FIG. 7. FIG. 8 shows the transistor device of FIG. 7 in a horizontal section plane B-B that extends parallel to the first surface 101 and goes through the body regions 22, and the source regions 23 and the drain region 25. FIG. 8 shows two elongated doped semiconductor regions, with each of these semiconductor regions forming the body regions 22 of a plurality of transistor cells. Second type transistor cells 14 only include the body region 22, first type transistor cells 13 include the body region 22 and the source region 23. In this embodiment, a plurality of device cells 13, 14 are adjacent in the longitudinal direction of the elongated semiconductor region forming the body regions 22.

The transistor device with the first type device cells 13 and the second type device cells 14 can be operated like a conventional MOS transistor. The operating principle is briefly explained in the following. For explanation purposes it is assumed that the MOS transistor is an n-type MOSFET. The MOSFET can be forward biased and reverse biased. An n-type MOSFET is forward biased when applying a positive voltage between the drain terminal D and the source terminal S. In the forward biased state the MOSFET can be switched on and switched off by applying a suitable drive potential to the gate terminal G. The MOSFET is switched on when a drive potential applied to the gate terminal G is such that there is a conducting channel in the body region 22 of the first type device cells 13 between the source regions 23 and the drift region 21. The MOSFET is switched off when the drive potential applied to the gate terminal G interrupts the conducting channel in the body region 22. Second type device regions 14 in which the source regions are omitted, are not active when the MOSFET is in the forward biased state, which means that there is no current flow in the second type device cells 14, so that no energy is dissipated in the second type device cells 14. Thus, by increasing the frequency of second type device cells 14 towards the center 12 of the cell field 10, where conventional transistor devices are strongly heated, helps to more equally distribute the temperature in the cell field 10.

An n-type MOSFET is reverse biased when a positive voltage is applied between the source terminal S and the drain terminal D. In this case, the MOSFET has the function of a diode (that is known as body diode) and conducts a current independent of a drive voltage applied to the gate terminal G. In the reverse biased state the current flows through the first type device cells 13 and the second type device cells 14.

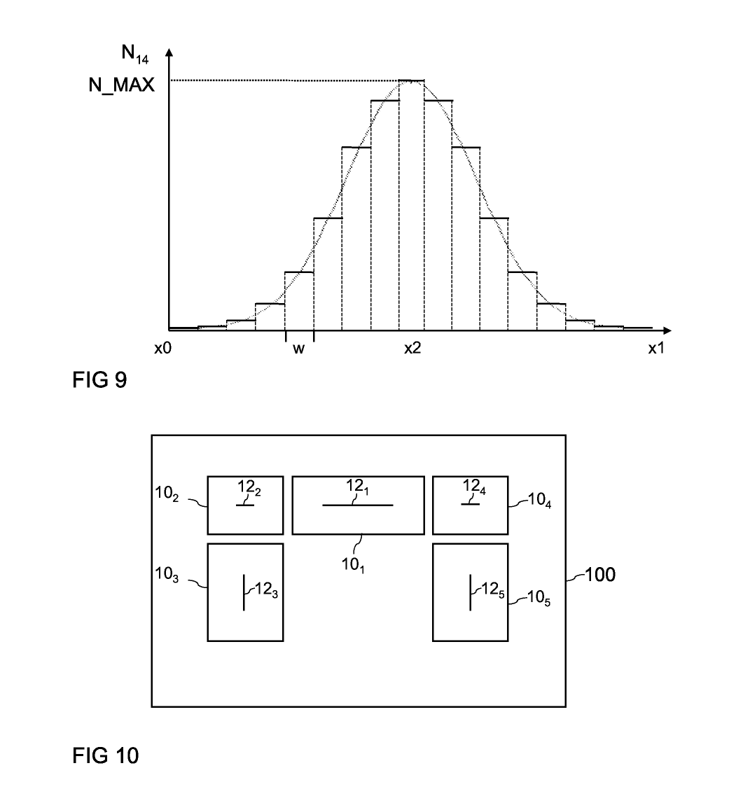

Referring to FIG. 9, the frequency of the second type device cells 14 can be normally distributed along the sequence of cell regions 15. FIG. 9 illustrates the frequency N₁₄ of the second type device cells in cell regions 15 that are located along a line, such as line L illustrated in FIG. 2, that is perpendicular to the edge 11 and extends from one edge section to an opposite section. In FIG. 9 ‘x0’ is the position of one edge section, such as edge section 11_{II} in FIG. 2, ‘x1’ is the position of the opposite edge section, such as edge section 11_{I} in FIG. 2, and ‘x2’ is the position of the center 12 of the cell field 10. The width ‘w’ of the individual cell fields 15 is along the line L. N₁₄ is the frequency of the second type device cells 14 in the individual cell fields 15. Thus, N₁₄ corresponds to the number of second type device cells 14 in one cell field 15 relative to the overall number of device cells in the cell field. For example, N_MAX is the maximum frequency of the second type device cells 14. This maximum is in a cell region 15 that includes the center 12 in this embodiment. For illustration purposes, in FIG. 9, besides the frequency of the second type device cells 14 the Gaussian curve is also illustrated. In the embodiment of FIG. 9, the frequencies of the second type device cells 14 along the line L are selected in accordance with the Gaussian curve. FIG. 9 depicts an ideal transistor with homogeneous environmental conditions like constant temperature above, below or around the transistor. In case of lateral or vertical disturbing heat-waves, affecting the transistor, the Gaussian shape must be changed in a way to achieve constant surface temperature after applying a specified energy.

The number of device cells 13, 14 in one cell field 15 is arbitrary. According to one embodiment, the number of device cells in the individual cell regions 15 is between 4 and 100. The overall number of device cells in the cell field 10 is dependent on desired current barring capability of the transistor device. The overall number of device cells can be between several thousand up to several millions.

Referring to FIG. 10, the cell field 10 can be subdivided in several sub-fields 10₁-10₅. In this case, the centers 12₁-12₅ of the individual sub-fields 10₁-10₅ are determined, and the second type device regions 14 are distributed in the individual sub-fields 10₁-10₅ in accordance with the explanation provided before.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A transistor device, comprising:
a plurality of device cells arranged in a cell field having an edge and a center, the individual device cells connected in parallel;
the device cells comprising a first type of device cells having a body region with a first size and a source region with a second size implemented in the body region, and comprising a second type of device cells having a body region of the first size and in which a source region is omitted or in which the source region is smaller than the second size;
the cell field comprising a plurality of non-overlapping cell regions, each comprising the same plurality of device cells, wherein there is at least one sequence of cell regions arranged between the edge and the center of the cell field in which the frequency of device cells of the second type monotonically increases from cell region to cell region in the direction of the center, and wherein one cell region of the sequence of cell regions includes or adjoins the center.

2. The transistor device of claim 1, wherein the frequency of second type device cells strictly monotonically increases in the sequence of cell regions.

3. The transistor device of claim 1, wherein the center of the cell field is equidistant to at least two opposite edge sections.

4. The transistor device of claim 1, wherein the monotonic increase of the frequency of the second type device cells is in accordance with a Gaussian curve.

5. The transistor device of claim 1, wherein the individual device cells are implemented as vertical device cells.

6. The transistor device of claim 1, wherein the individual device cells are implemented as lateral device cells.

7. The transistor device of claim 1, where the monotonic increase of the frequency of the second type device cells is not in accordance with a Gaussian curve due to lateral heat wave disturbance from adjacent circuit regions.
